(19) United States
(12) Patent Application Publication
(10) Pub. No.: US 2026/0223326 A1
(43) Pub. Date: Jul. 30, 2026

(54) ENCLOSED PHASE CHANGE IMMERSION COOLING

(71) Applicant: HEWLETT PACKARD ENTERPRISE DEVELOPMENT LP, Spring, TX (US)

(72) Inventor: Aijun Liu, Beijing (CN)

(21) Appl. No.: 19/041,109

(22) Filed: Jan. 30, 2025

(51) Int. Cl. H05K 7/20; H05K 5/02; H05K 5/03; H05K 5/06

(52) U.S. Cl. CPC H05K 7/203; H05K 5/0247; H05K 5/03; H05K 5/067; H05K 5/069; H05K 7/20418; H05K 7/20663

(57) ABSTRACT

An outdoor information processing device comprises a housing. The housing comprises a hollow interior volume sealed air-tight from an exterior environment and heat dissipation structures on an exterior of the housing. A coolant is disposed in the hollow interior volume of the housing. A portion of the coolant is in a liquid phase collected in a pool in the housing and a portion of the coolant being in a vapor phase above the pool. An information processing system board comprising electronic components is disposed in the hollow interior volume and immersed in the pool of the liquid phase of the coolant. The coolant is configured to transfer heat from the electronic components into the housing via the coolant going through a repeated phase-change cycle.

Some networking devices (such as wireless access points) and other edge devices (e.g., edge servers) are designed for use in challenging environments where they will be exposed to dust, water, and/or other contaminants. Examples of these challenging environments include outdoors locations, indoors locations with high contaminant levels (e.g., dirty industrial applications), and the like. These devices will all be referred to herein as “outdoor devices” for simplicity, even though some may be used indoors. To protect the sensitive electronics of these outdoor devices, such as a main system board, from the contaminants, the electronics may be disposed in a housing which is sealed from the external environment.

### BRIEF DESCRIPTION OF THE DRAWINGS

The present disclosure can be understood from the following detailed description, either alone or together with the accompanying drawings. The drawings and related description of the figures are included to provide a further understanding of the present disclosure and are incorporated in and constitute a part of this specification. The drawings illustrate one or more nonlimiting aspects and implementations of the present teachings and together with the description explain certain principles and operation. In the drawings:

FIG. 1 is a block diagram of a system for enclosed phase change immersion cooling.

FIG. 2 is a front elevation view of an information processing device using enclosed phase change immersion cooling.

FIG. 3 is a rear elevation view of an information processing device using enclosed phase change immersion cooling.

FIG. 4 is a side elevation view of an information processing device using enclosed phase change immersion cooling.

FIG. 5 is a bottom perspective view of the information processing device of FIG. 2.

FIG. 6 is a front and top perspective view of an information processing device using enclosed phase change immersion cooling.

FIG. 7 is a front and bottom perspective view of an information processing device using enclosed phase change immersion cooling.

FIG. 8 is a cross-section of the information processing device using enclosed phase change immersion cooling of FIG. 2 taken along line 8-8.

FIG. 9 is a cross-section of the information processing device using enclosed phase change immersion cooling of FIG. 6, taken along line 9-9.

FIG. 10 is a cross-section of the information processing device using enclosed phase change immersion cooling of FIG. 7 taken along line 10-10.

### DETAILED DESCRIPTION

With outdoor devices, the sealed nature of the housing poses challenges for cooling the electronics of the outdoor devices. An approach commonly used to cool standard indoor servers and networking devices is to blow air through the device and over the heat generating components thereof, but this approach is unlikely to be suitable in an outdoor device given that the electronic components are disposed in a sealed housing, which prevents air from flowing through the device. Another approach used to cool indoor devices is liquid cooling (sometimes called direct liquid cooling or “DLC”) in which liquid is circulated through a loop which passes through the system, and inside the system cold plates are thermally coupled to the heat generating components and the liquid coolant, thereby allowing the liquid to absorb heat and carry it out of the system, where it is later extracted from the liquid by a heat exchanger. The sealed housing of the outdoor devices does not pose a problem for liquid cooling, but unfortunately liquid cooling is still unfeasible for many outdoor devices because the liquid cooling infrastructure needed to support a liquid cooling loop (such as a coolant distribution unit (CDU), heat exchanger, facility coolant supply line, etc.) is usually not available, and would be cost prohibitive to provide, in the edge locations where outdoor devices are usually deployed.

Thus, in such outdoor devices, cooling is often provided by placing one or more conductive thermal transfer elements (e.g., metal bars, heat pipes, etc.) in contact with and extending between the electronic components and the housing, thereby thermally coupling the housing with the electronic devices. This allows heat to be transferred from the electronic components into the housing, and the housing can then dissipate the heat passively into the surrounding environment, such as via passive (or forced) convection and radiation.

However, information processing components, such as CPUs, are increasing in power usage and heat generation, which is making it increasingly difficult to adequately cool the sealed outdoor devices using the conductive thermal transfer elements. In particular, the rate of heat transfer which can be achieved using the conductive thermal transfer elements can be somewhat lower than is needed, in some cases. This may result in the conductive thermal transfer elements forming a bottleneck in the heat dissipation path. In other words, even if the housing is capable of dissipating heat at a sufficiently high rate to, in theory, adequately cool the electronic components, the thermal transfer elements may transfer the heat into the housing at a lower rate, preventing the full heat dissipation capability of the housing from being realized and potentially allowing some components to overheat. The relatively low heat transfer rates provided by the conductive thermal interface elements may result, in some cases, from poor thermal interfaces between the conductive thermal interface elements and the electronic components. These poor thermal interfaces may happen because it is difficult to precisely arrange the conductive thermal transfer elements relative to the electronic components given that the housing is sealed. Highly precise manufacturing tolerances might allow for better thermal interfaces to be realized, but this may greatly increase the price of the systems, which may not be feasible in some cases.

In addition, the conductive thermal transfer elements may provide uneven cooling across the various electronic components. In some systems, some of the components are not placed in direct contact with a conductive thermal transfer element, instead relying on indirect cooling via heat conduction through the copper wires electrically connecting the components of the system together. This can result in the components which are not directly in contact with a conductive thermal transfer element receiving less cooling than those which are in direct contact. Furthermore, even if all components can be placed in contact with a conductive thermal transfer element, the heat conduction pathways provided between the various electronic components and the housing may vary in quality, which can result in some electronic components receiving less cooling than others. In addition, the copper wires extending between the components can also allow heat generated by hotter components, such as the CPU, to flow into other components. All of these phenomena can result in uneven cooling of the components, meaning that some electronic components may receive sufficient cooling and operate at desired temperatures but other components may receive insufficient cooling and overheat. In particular, it has been found that, even if the CPU or other hot components are being adequately cooled, some heat sensitive components, such as a trusted platform module (TPM), may become overheated.

Thus, for a variety of reasons, it can be challenging to cool the components of an outdoor device. Accordingly, the performance of outdoor devices may be limited below their maximum capabilities to avoid overheating, or if allowed to run at their full performance some components could overheat which could result in premature failure.

To address these issues, in examples disclosed herein, the housing of the outdoor device is partially filled with a dielectric liquid non-flammable coolant and the electronic components (e.g., main system board) of the device are immersed within the liquid. The coolant is chosen so that it has a boiling temperature that is lower than or equal to a desired operating temperature for the electronic components, and thus during operation the coolant may change phases between liquid and vapor (gas), resulting in the interior of the housing having a pool of liquid-phase coolant in a bottom portion and a volume of vapor-phase coolant in an upper portion. Heat is transferred efficiently from the electronic components into the housing via the coolant going through a phase-change cycle.

Specifically, the coolant cools the electronic components via going through a repeated phase-change cycle comprising: (1) the liquid in contact with the electronic components absorbs heat therefrom, cooling the electronic components and heating the liquid until it reaches its boiling point, at which time some of the liquid converts from liquid to vapor (boils), and this phase change absorbs even more heat from the electronics due to the latent heat of vaporization, (2) the heated vapor then moves, via natural convection, into contact with the housing which causes the vapor to condense back into liquid on the housing, with the phase change releasing heat into the housing due to the latent heat of condensation and cooling the newly condensed liquid slightly below the boiling point, (3) the heat received by the housing from the vapor is dissipated into an external environment via passive convection and radiation, and (4) the cooler condensed liquid returns to the liquid pool via gravity, where it can absorb more heat from the electronics. The housing may be sealed relative to the external environment to keep external contaminants out. Beneficially this sealing may also allow for the liquid and vapor phases of the coolant to be retained within the housing.

An advantage of the above-described arrangement is that the liquid naturally flows around and contacts all portions of the system board, which allows all of the electronic components to be in simultaneous contact with the liquid coolant and cooled uniformly by this coolant. This is in contrast to the conductive thermal transfer elements which may extract heat from some components more readily than from others, resulting in uneven cooling. Moreover, the rate of heat transfer from the components to the housing is extremely fast, much faster than can be provided using copper or other heat transfer devices to thermally couple the components to the housing. Thus, the maximum rate of heat dissipation of the overall device is limited only by the dissipation capabilities of the housing, and not by any bottleneck in the transfer of heat from the components to the housing. This allows all of the major components to be kept at or below the boiling temperature of the coolant, and thus when the coolant is chosen appropriately to have a boiling point equal to or lower than the desired maximum operating temperature, all components can be kept at temperatures equal to or below the desired maximum operating temperature.

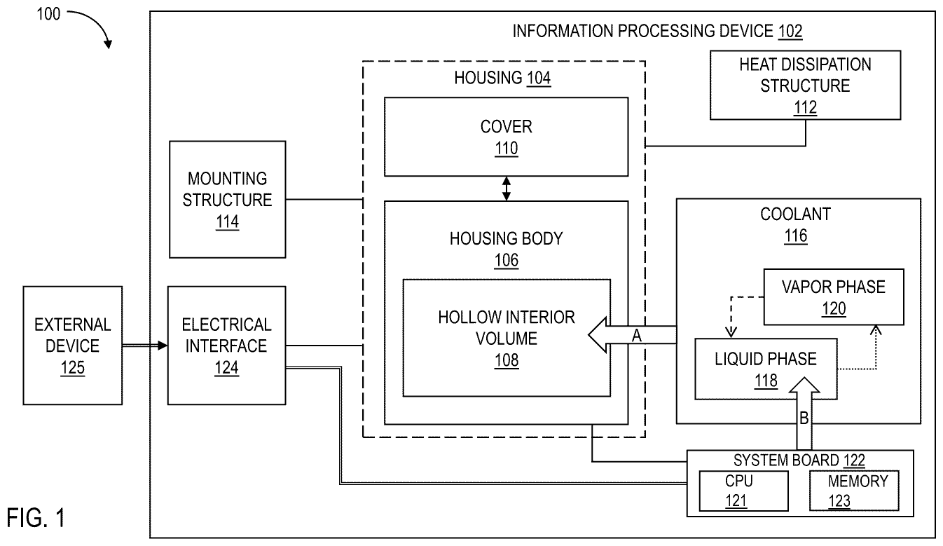

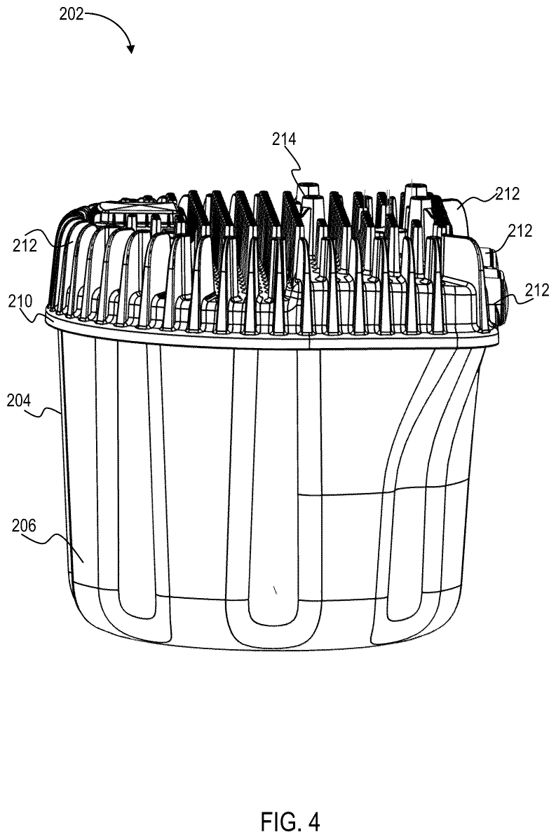

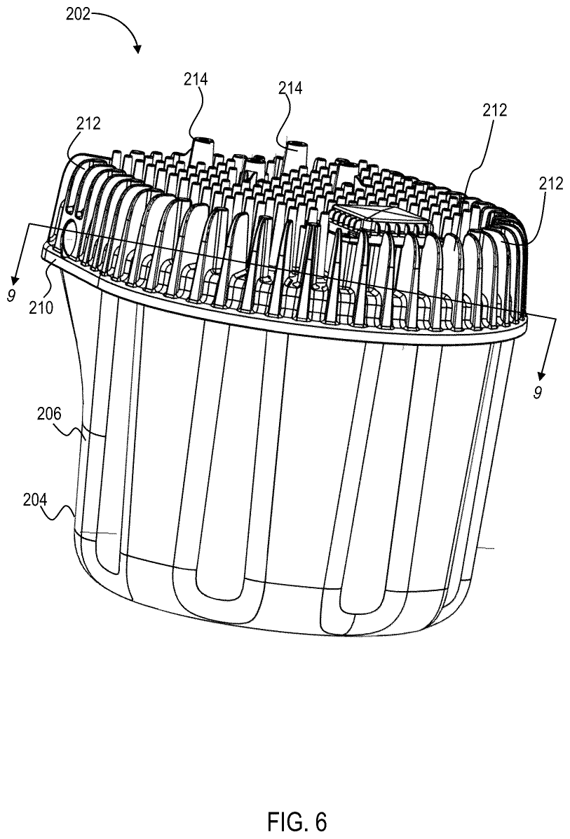

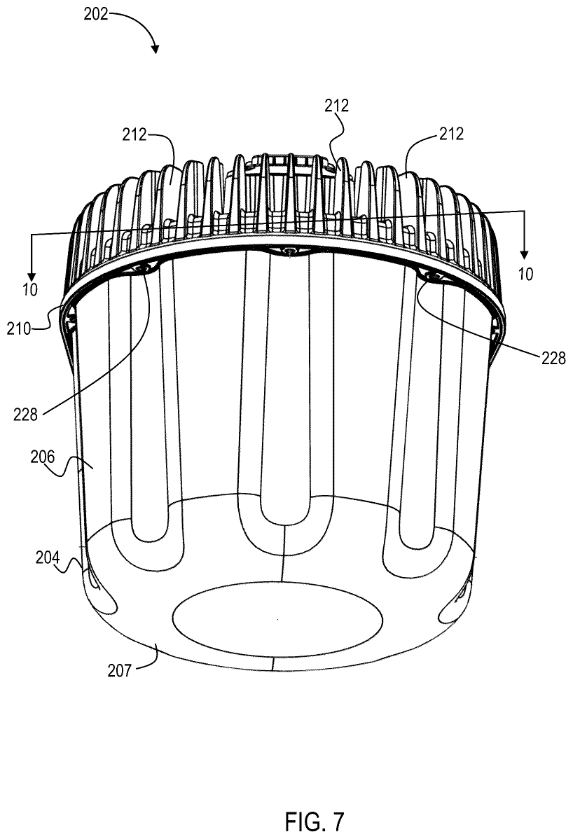

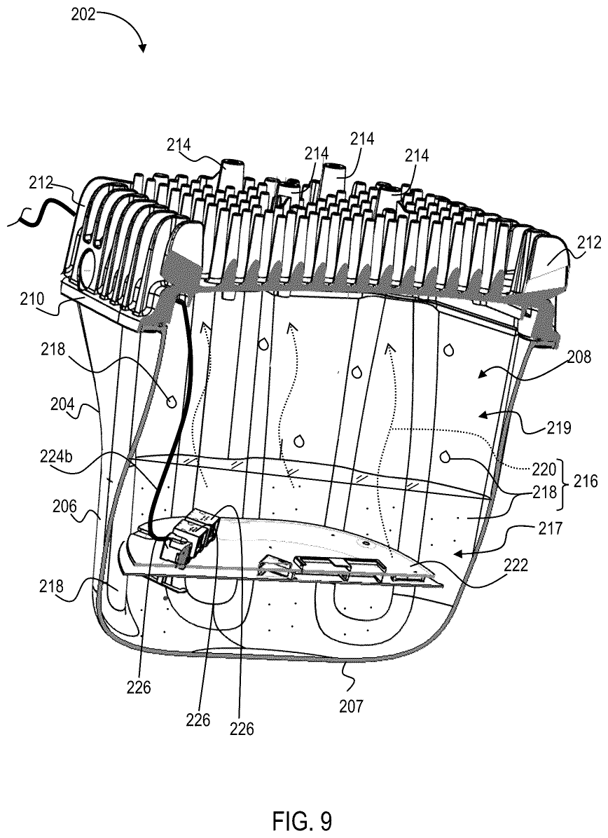

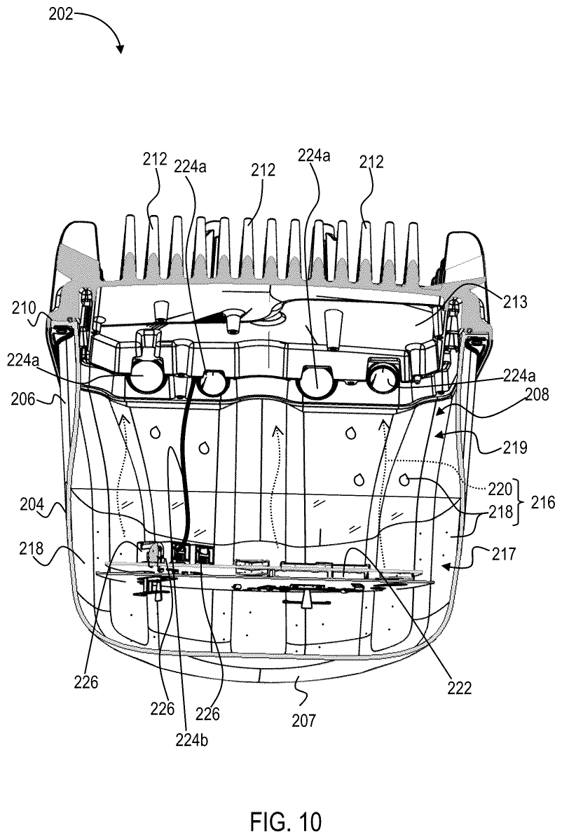

These and other examples will be described in greater detail below in relation to FIGS. 1-11.

FIG. 1 illustrates an example system 100. FIG. 1 is schematic in nature, and it should be understood that FIG. 1 is not intended to illustrate specific shapes, dimensions, positional relationships, or other structural details accurately or to scale, unless otherwise noted herein. Implementations of information processing system 100 may have different numbers and arrangements of the illustrated components. In addition, components illustrated in FIG. 1 may be omitted from some examples disclosed herein, and components which are not illustrated in FIG. 1 may also be included in some examples disclosed herein. In FIG. 1, physical connections (e.g. physical attachment and/or support) between components are indicated conceptually by solid lines extending between the components. Intermittent attachments are indicated conceptually with solid-line arrows. Electrical connections are indicated by doubled solid lines. Certain positional relationships are indicated by thick white-filled arrows. Phase changes and/or motion of coolant is indicated by dashed-line arrows and/or dotted-line arrows.

System 100 includes an information processing device 102. Information processing device 102 may be a networking device, such as a wireless access point, an edge device, such as an edge server, or any other information processing device. More particularly, in some examples device 102 may be an outdoor information processing device 102, meaning that its electronic components are sealed off from an external environment, as discussed further below. Information processing device 102 may include a housing 104, which may be comprised of a housing body 106 and a cover 110 which may be engaged with housing body 106. When cover 110 is engaged with housing body 106, housing 104 may be a closed environment; however, cover 110 may be removed from housing body 106 to allow access to housing body 106. More particularly, housing body 106 may define a hollow interior volume 108, with housing body 106 defining the side and bottom boundaries of the hollow interior volume 108 and the cover 110 defining an upper boundary of the hollow interior volume 108.

Hollow interior volume 108 may be sealed from an exterior environment when cover 110 is coupled to housing body 106. More particularly, when cover 110 is coupled to housing body 106, an air-tight seal may separate the housing interior volume 108 and the environment, preventing external contaminants from entering the housing interior volume 108.

In some examples, at least one heat dissipation structure 112 may be located on an exterior of housing 104. As used herein, a heat dissipation structure refers to a structure designed to dispel excess heat from a system into an exterior environment. Heat dissipation structure 112 may be passive (i.e., the heat dissipation structure naturally dissipates heat) or forced (i.e., the heat dissipation structure receives aid, such as a fan, to dissipate heat). The heat dissipation structure 112 may be disposed on the cover 110 of housing 104, allowing heat to be released from the top of information processing device 102; however, examples are not so limited and heat dissipation structure 112 may be located elsewhere on housing 104, such as on housing body 106.

In some examples, heat dissipation structure 112 may be a heatsink. A heatsink refers to a device that receives heat from a body, usually via conduction, and which has multiple surface-area increasing protrusions that protrude into a gas cooling medium and dissipate the heat into the gas cooling medium, such as air. The protrusions increase the total surface area exposed to the gas cooling medium and thereby increase a rate of heat transfer thereto. The protrusions may include skived fins, cast fins, pins (also sometimes called pin fins), or other shapes. In some examples, heat dissipation structure 112 may include a heatsink with a plurality of heat dissipating fins on an external surface of housing 104. The heat dissipating fins may absorb heat from the housing 104 via conduction and, due to having an increased surface area exposed to the air, efficiently release the heat.

In some examples, the heat dissipation structure 112 may include a heatsink which is integrally connected with the housing 104, meaning that the housing and the heatsink are formed as parts of the same unitary (monolithic) body. For example, the heatsink and housing 104 may be formed together by machining from the same solid block of metal, by being cast together in the same casting, by being additively manufactured together as a single body (e.g., 3D printed, etc.). In such examples, because the heatsink and housing 104 are integrally connected, heat which is transferred into the interior surface of the housing 104 (as described below) can be efficiently transferred into the protrusions via conduction without having to pass through any thermal interfaces.

In other examples, the heat dissipation structure 112 may include a heat sink which is formed separately form the housing 104 and then later attached thereto. This introduces a thermal interface between the two, which can reduce the heat transfer rate. But, in some cases, the overall heat dissipation rate may be sufficient despite this additional thermal interface.

In some examples, the heat dissipation structure 112 may include a heat sink having protrusions which are configured to facilitate passive heat dissipation. Protrusions that facilitate passive heat dissipation include cast fins or pins, which have relatively wide spacings between the protrusions to allow for easier natural convection without forced airflow. This is in contrast to skived fins, which are very finely spaced to maximize surface area, but which generally need to have forced airflow due to the fine spacing.

In some examples, the heat dissipation structure 112 and/or other portions of the housing 104 may be configured to have a relatively high emissivity. This allows the body to passively dissipate heat by thermal radiation into the external environment, further increasing the heat dissipation rate. All materials thermally radiate, but those with high emissivity do it at a higher rate. The emissivity of a body depends on not only the type of material, but also the condition of the surface of the material, such as whether its polished or rough or whether it is oxidized or not. Materials with higher emissivity can also be coated or plated onto the surface of lower emissivity materials to improve the emissivity. Generally, “high emissivity” as used herein refers to an emissivity of at least 0.7. Some examples of suitable materials with high emissivity include: anodized aluminum; anodized beryllium; various black paints, enamels, or lacquers; various oxidized metals (steel, nickel, copper, etc.), glass (e.g., pyrex), wrought iron, and others.

The housing body 106 may further include at least one mounting feature 114 coupled to the housing body 106. Mounting feature 114 may be a bracket, an aperture, a screw hole, or any other means by which housing 104 may be coupled to an external surface at housing body 106. More particularly, mounting feature 114 may be configured to engage with a corresponding mounting feature on an external surface, such as a wall, thus allowing information processing device 102 to be installed at a desired location.

A coolant 116 is disposed within the hollow interior volume 108, as indicated by arrow labeled “A” in FIG. 1. The coolant 116 may be an electrically non-conducting material that is liquid at room temperatures, such as dielectric fluid. In cooling applications, such as in the system 100, the coolant absorbs heat from components of the system and releases the heat into a cooling device, which in the case of the system 100 is the housing 104. More specifically, the coolant 116 is a two-phase coolant, meaning it is engineered to transport heat by changing between liquid and vapor (gas) phases during operation of the device. In particular, the coolant 116 has a boiling point which is near the desired operating temperature of the components, which means that the components can bring the coolant 116 to boiling during operation. This boiling absorbs heat from the components, while also facilitating efficient transport of that heat into the housing 104, as will be described below. In some embodiments, the coolant 116 may be Novec™ 7300 Engineered Fluid, manufactured by 3M™, although examples are not so limited and other varieties of coolant may be used.

A portion of coolant 116 may be in a liquid phase 118. In the liquid phase 118, the coolant 116 may be disposed towards the bottom of the housing body 106 and thus at a lower portion of the hollow interior volume 108. The liquid phase 118 of coolant 116 forms a pool within the hollow interior volume 108. Electronic components of the device 102, including the system board 122 which is discussed below, are immersed (submerged) within the pool of liquid phase 118 coolant 116, as indicated by the arrow labeled “B” in FIG. 1.

Another portion of coolant 116 may be in a vapor phase 120. As used herein, a vapor phase refers to a state in which a substance, such as coolant 116, exists as a gas. The vapor phase 120 of coolant 116 may be disposed above the liquid phase 118; however, vapor phase 120 of coolant 116 remains within the hollow interior volume 108.

System 100 may further include a system board 122. The system board 122 may be a motherboard that includes a central processing unit (CPU) 121, a memory 123, and other core components (not illustrated), but examples are not so limited and any system board may be used. System board 122 may be disposed within the hollow interior volume 108 of housing body 106 and more particularly may be immersed within the pool formed by the liquid phase 118 of coolant 116, such that coolant 116 surrounds system board 122 and the electronic components, including CPU 121 and memory 123, disposed thereupon. System board 122 may be coupled to the housing 104 (e.g., to housing body 106) to secure and support the system board 112.

Each electronic component on system board 122, including CPU 121 and memory 123, may have an individual maximum operating temperature, which is the maximum temperature at which the respective component is designed to be operated over the long term. This individual maximum operating temperature may be specified by a manufacturer of the component. The maximum operating temperature may reflect the highest temperature at which the component can operate without risking damage to the electronic components. Each electronic component may have a distinct individual maximum operating temperature, and the maximum operating temperature may depend on factors such as the materials making up the individual component, default settings (e.g., clock speed on a processor such as CPU 121), among other factors. In addition, system board 122, and electronic components disposed thereon, may generate heat through operation. The components may also have a desired operating temperature, which represents a maximum temperature at which the manufacturer of the device 102 intends to operate the component. This desired operating temperature may be equal to the maximum operating temperature, in some cases, or the desired operating temperature may be different from the maximum operating temperature in other cases. For example, in some cases a desired operating temperature of a component may be set lower than a maximum operating temperature for the component in order to reduce energy consumption, increase the lifespan of the component, or for other reasons.

As described previously, coolant 116 may have a portion in a liquid phase 118 and a portion in a vapor phase 120. Coolant 116 may move through a phase-change cycle, thus moving between the liquid phase 118 and the vapor phase 120. More particularly, the liquid portion 118 of coolant 11 may boil when the heat generated by the electronic components on system board 122 corresponds to the boiling point of the coolant 116. In some examples, the boiling point of the coolant 116 may be lower than or equal to a lowest one of the individual maximum operating temperatures of the electronic components on the system board 122. For example, CPU 121 may have a maximum operating temperature of 99 degrees Celsius, while memory 123 may have a maximum operating temperature of 102 degrees Celsius. Thus, the boiling point of coolant 116 may be less than or equal to 99 degrees Celsius, as the CPU 121 has the lowest maximum operating temperature of the components on system board 122. In some examples, the coolant 116 may have a boiling point of between 97 and 99 degrees Celsius, such that neither the CPU 121 nor the memory 123 exceed their respective maximum operating temperatures. Examples are not so limited, however, and components may have other maximum operating temperatures. Furthermore, in some examples, the boiling point of the coolant 116 may be equal to or lower than the lowest one of the desired operating temperatures of the components.

Boiling the coolant 116 in the liquid phase 118 results in the coolant 116 moving into the vapor phase 120, as shown by the dotted line in FIG. 1. Movement into the vapor phase 120 from the liquid phase 118 also includes bringing heat generated by the system board 122.

The vapor phase 120 of coolant 116 moves towards the cover 110 of housing 104, where it eventually comes in contact with a portion of cover 110 facing into the hollow interior volume 108. As described previously, a heat dissipation structure 112 may be located on an exterior of the cover 110 and is thermally coupled (directly or indirectly) with the interior surface of the cover 110. When the coolant 116 in the vapor phase 120 contacts the interior surface of the cover 110, the heat carried by the vapor phase 120 is transferred into the cover 110, and from there the heat is transferred via conduction into the heat dissipation structure 112. This removal of heat from the vapor phase 120 cools the coolant 116 and allows condensation from the vapor phase 120 to the liquid phase 118, shown by the dashed arrow. In this manner, the coolant 116 is able to return to the liquid phase 118 after transferring heat generated by system board 122 out of the housing 104 via the heat dissipation structure 112. As a result, coolant 116 is able to continuously cool system board 122 and the electronic components, such as CPU 121 and memory 123, coupled thereto.

System 100 may include one or more external devices 125 and device 102 may further include at least one electrical interface 124 to allow electrical connection of the device 102 to the external device(s) 125. Electrical interface 124 may be coupled to an exterior of housing 104 and is electrically connected with the system board 122 through the housing 104 of information processing device 102. The electrical interface 124 comprises one or more connectors, ports, plugs, or other such devices which are configured to establish electrical connections with one or more external electrical devices 199, such as external power sources and/or external information processing devices. These connectors, ports, plugs, or other such devices are, in turn, electrically connected to the system board 112, for example by wires, cables, or other conductors which extend through the housing 104 via air-tight passages, or via wireless electromagnetic connections. When electrical interface 124 is connected to an external power source (not shown), system board 122 may receive electrical power from the external power source via the electrical interface 124. In addition, the connection between system board 122 and electrical interface 124 may allow the exchange of electrical communications between system board 122 and electrical interface 124, which may aid in the functionality of system board 122 and the components coupled thereto. In some examples, the electrical interface 124 may be physically connected to system board 122, while in other examples, the connection between electrical interface 124 and system board 122 may be wireless. The electrical interface 124 may include at least one power supply portion which supplies electrical power to the system board 122. This power supply portion of the electrical interface 124 may include a power input port (such as a DC barrel jack, for example) configured to removably mate with an external power cord (which is in turn plugged into a power source), a permanently connected power cord configured to plug into an external power source, a power-over-Ethernet (PoE) port, a solar cell, etc. The electrical interface 124 may also include one or more data communication portions which communicate data with the system board 122. These data communication portions of the electrical interface 124 may include an ethernet connector, an antenna, an optical transceiver, or any other suitable data communication interface capable of electrical connection and/or electrical communication exchange with an external device. The external devices 125 may include an external power source, such as an electrical outlet, power supply, generator, battery, solar cell, etc. The external devices 199 may also include one or more information processing devices (e.g., networking devices, servers, etc.) which are separate from the device 102 which exchange data communications with the device 102.

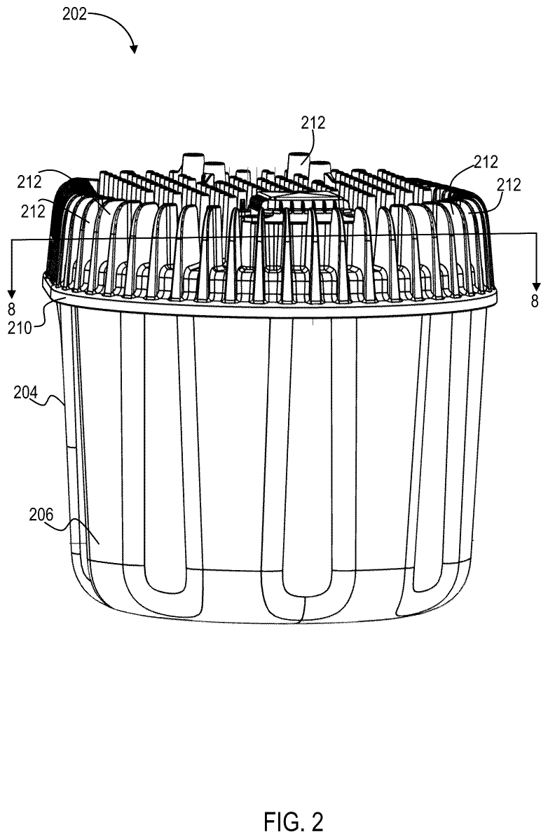

Turning to FIGS. 2-10, an example information processing device 202 is shown. Information processing device 202 may be one implementation example of information processing device 202 shown in and described with respect to FIG. 1 and may be used in a system such as system 100, described with respect to FIG. 1. Information processing device 202 thus comprises components which correspond to (i.e., are implementation examples of) components of the information processing device 202, and the correspondence between such components is indicated herein by the components having reference numbers with the same last two digits, such as 112 and 212. Aspects of the information processing device 102 and its components described above may also be applicable to the information processing device 202 and its corresponding components, but the information processing device 102 and its components are not limited to the information processing device 202 and its components, which are just one example of how the information processing device 102 may be implemented. In some instances, aspects of the information processing device 102 already described above, which are also applicable to the information processing device 202, are not described below to avoid duplicative description.

Information processing device 202 comprises a housing 204, with housing 204 further comprising a housing body 206 and a cover 210. It should be noted that the lines depicted in the figures on housing body 206 are contour lines and do not represent a separate portion of housing body 206. Housing 204 may have a diameter d, which may be between 200 millimeters and 300 millimeters. Housing 204 may also have a weight, which may be around two kilograms. The information processing device 202 may have a weight of around five kilograms including coolant, a system board, and other components.

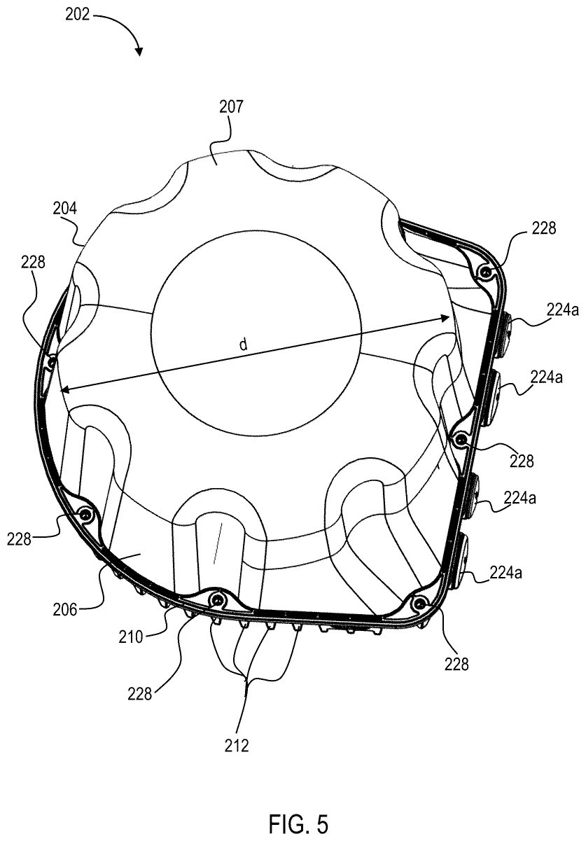

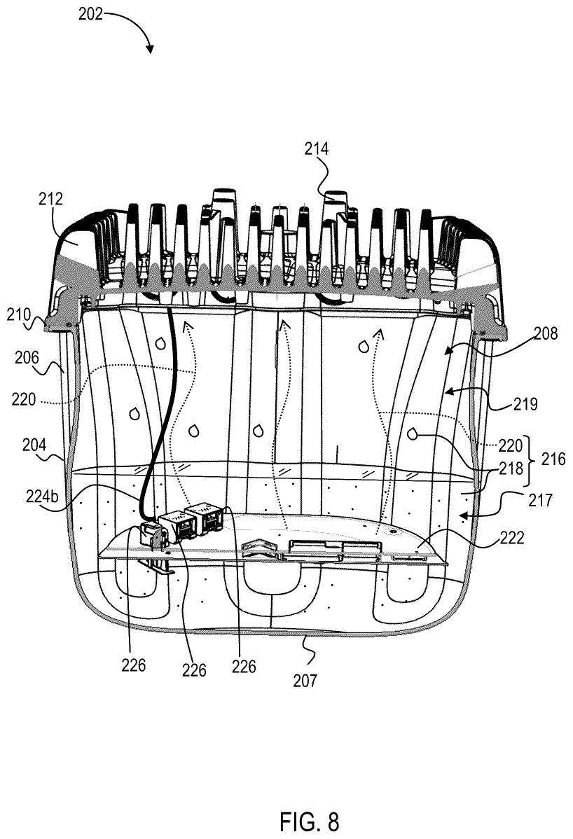

As shown in FIGS. 8-10, housing body 206 defines a hollow interior volume 208. More particularly, as shown in FIGS. 8-10, hollow interior volume 208 is bounded by a bottom 207 of the housing body 206 and by cover 210 of housing 204, with housing body 206 extending between the bottom 207 and the cover 210. Cover 210 may be removably coupled to housing body 206. In some examples, in the coupled state, attachment features 228, shown particularly in FIG. 5, may be used to fix cover 210 to housing body 206. Attachment features 228 may be screws, snap-fit connectors, pins, or any other suitable attachment feature.

When cover is 210 is coupled to housing body 206, hollow interior volume 208 may be sealed from an external environment. More particularly, coupling cover 210 to housing body 206 may provide an air-tight seal between the exterior environment and the hollow interior volume 208. As a result, hollow interior volume 208 may be protected from contaminants.

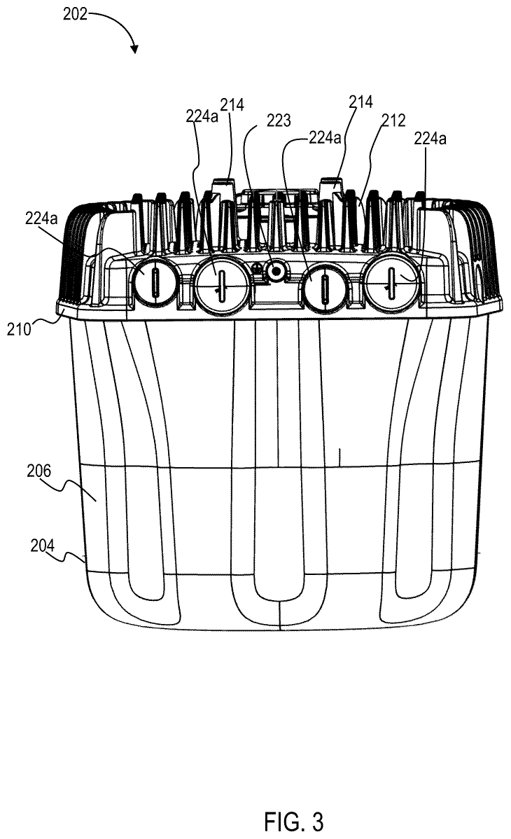

Housing 204 may further include at least one mounting feature 214. As shown in, e.g., FIG. 3, mounting feature 214 may be one of a plurality of mounting features 214; however, examples are not so limited and a single mounting feature 214 may be used. In addition, while the mounting features 214 shown in FIG. 3 are screw-like, examples are not so limited, and other types of mounting features 214 may be used. For example, mounting feature 214 may be a bracket disposed on housing 204 and configured to engage with a corresponding attachment feature on an exterior surface, such as a wall, thus allowing information processing device 202 to be mounted. Mounting features 214 may be configured to engage with a corresponding attachment feature, such as an aperture, on a corresponding mounting bracket disposed on an external surface. In some examples, the bracket may be one of a wall bracket and a ceiling bracket; thus information processing device 202 may be mounted, using mounting features 214, to a wall or a ceiling, with the particular mounting location being decided based on factors including environment and system considerations.

Housing 204 further includes a heat dissipation structure 212 comprising a plurality of heat dissipating fins. Heat dissipation structure 212 may be disposed on cover 210, as shown in FIGS. 2-10; however, examples are not so limited and in other examples other parts of housing 204, such as housing body 206, may include heat dissipation structures in addition to or in lieu of the cover 210.

In this example, heat dissipation structure 212 takes the form of a heatsink comprising a plurality of heat dissipating fins extending outwardly from housing 204. As shown in FIGS. 2-10, the fins may extend upwardly from the cover 210. In this example, the fins may be configured to allow for passive dissipation of heat. Specifically, the fins are somewhat thick in a thickness dimension, narrow in a width dimension, and somewhat widely spaced. The fin's shape and wide spacing makes it easier for air to passively move through the fins, or in other words for passive convection to take place, thus allowing for cooling to occur even though no force airflow is provided. By contrast, other heat dissipation structures designed for forced airflow heat dissipation may include skived fins that are be somewhat thin (in the thickness dimension), wide (in the width dimension) and somewhat closely spaced, which allows for greater surface area and thus better cooling but also requiring a fan to force adequate airflow between the fins. Although the structures 212 are designed to enable passive dissipation, it is also possible to provide the device 202 with active airflow if it is desired to supplement the cooling capabilities of the system, for example by mounting a fan on or next to the device 202.

In the example illustrated in FIGS. 2-10, the heat sink of the heat dissipation structure 112 is formed as part of cover 210, i.e., they are integrally connected (part of the same monolithic body). Because the fins are integrally connected with the cover 210, a conductive heat transfer path is present between an inner surface 213 of cover 210 and the fins. Accordingly, heat transferred to the inner surface 213 of the cover 210 by the vapor-phase coolant 220 can flow by conduction into the fins. The cover 210 may be formed from a thermally conductive material, and therefore the rate of heat conduction from the inner surface 213 into the fins may be relatively high.

FIGS. 8-10 show cross-sectional views of FIGS. 2, 6, and 7, respectively, allowing the hollow interior portion 208 of information processing device 202 to be seen. It should be noted that the greyscale portions in FIGS. 8-10 represent the location of the individual cross-section.

As shown in FIGS. 8-10, hollow interior portion 208 includes a coolant 216. More particularly, coolant 216 is divided into a liquid portion 218 and a vapor portion 220, with the liquid portion 218 disposed primarily in a pool 217 and with vapor portion 220 disposed primarily in a volume 219 above the pool 217. (Note that some of the liquid portion 218 may be located temporarily in volume 219 and some of the vapor portion 220 may be located temporarily in pool 217, due to phase changes which occur, as discussed below). It should be noted that the marks (dots) on liquid portion 218 in the figures serve to visually differentiate the liquid portion 218 of coolant 216 from other components contained within hollow interior volume 208, but are not intended to represent objects. Vapor portion 220 is represented by dotted-line arrows in the figures, but it should be understood that the vapor portion 220 of coolant 216 is in a gaseous state and thus may spready throughout the volume 219. Coolant 116 may be a dielectric fluid, although examples are not so limited.

A system board 222 is disposed within hollow interior volume 208, and may more particularly be disposed in the pool 217 such that system board 222 and electronic components 226 disposed on system board 222 are immersed within the liquid portion 218 of coolant 216. In some examples, electronic components may include a central processing unit (CPU) and a memory, such as CPU 121 and memory 123, respectively, discussed with respect to FIG. 1. However, examples are not so limited and other or additional electronic components may be present on system board 222.

System board 222 is coupled to an electrical interface 224, with electrical interface 224 formed from exterior portions 223 and 224a and interior portion 224b. Exterior electrical interface portion 224a may disposed on an exterior portion of housing 204, as shown in FIG. 3. More particularly, exterior electrical interface portion 224a may be ports through which an electrical connection can be made. In FIG. 3, exterior electrical interface portion 224a is shown with plugs installed to seal the port from an exterior environment when not in use. Exterior electrical interface portion 223 is a grounding connection point to provide a connection to electrical ground for the electrical interface 224.

Interior electrical interface portion 224b, shown in FIGS. 8-10, may comprise a wire or other connection, which may extend from system board 222 to exterior electrical interface portion 224a. In this manner, system board 222 may receive electrical power, allowing electronic components 226 to function. In addition, electrical interface 224 may be allow the exchange of electrical communications between the electrical interface 224 and the system board 222. While exterior electrical interface portion 224a takes the form of a plug-in interface portion and interior electrical interface portion 224b shows a wire, examples are not so limited and wired or wireless connections may be used. Examples of electrical interface 224 include an ethernet connector, a power input port, and an antenna, although examples are not so limited. In addition, although FIGS. 3 and 8-10 show only one electrical interface 224, more than one electrical interface 224 may be present. For instance, in some examples, information processing device 202 may have both an antenna and a power input port, although examples are not so limited.

As described with respect to FIG. 1, each electronic component 226 on system board 222 may have a certain maximum operating temperature, which represents the maximum temperature the electronic component 226 can reach before risking damage to the component. When system board 222 is coupled with electrical interface 224, the electronic components 226 receive electrical power and thus generate heat as a result of their use. Thus, coolant 216 may be used to remove heat from the electronic components 226, allowing the electronic components to remain at a safe operating temperature.

More particularly, coolant 216 may undergo a repeated phase-change cycle to transfer heat from the electronic components 226 to the housing 204. In some examples, the repeated phase-change cycle may begin with the liquid portion 218 of coolant 216 in the pool 217 boiling. The boiling point of coolant 216 may correspond to a temperature that is lower than or equal to a lowest maximum operating temperature of electronic components 226. That is, as described previously, each electronic component 226 may have a maximum operating temperature, and in some examples, each electronic component 226 may have a separate maximum operating temperature. Thus, coolant 216 may be selected to have a boiling point that is lower than or equal to the lowest maximum operating temperature of the individual maximum operating temperatures. In some examples, the coolant 216 may have a boiling point of between 97 and 99 degrees Celsius; however, examples are not so limited and coolants 216 having other boiling points may be used depending on the specific electronic components 226 on system board 222.

As coolant 216 boils, portions of the liquid phase 218 turn to vapor, becoming part of vapor phase 220. This phase change is shown by an upward dotted arrow. The newly formed vapor bubbles up through the pool 217 and enters the volume 219 above the pool 217, joining the other existing portions of the vapor phase 220 in the volume 219. By boiling and entering vapor phase 220, coolant 216 absorbs heat from the electronic components 226 and carries the heat away therefrom and out of the liquid phase 218. The vapor may spread through the volume 219 by passive convection, and portions of the vapor will occasionally come into contact with the inner surfaces of the housing 204, including the inner surface 213 of the cover 210. Once a portion of the vapor phase 220 coolant 216 contacts the inner surface 213, it may condense thereon because the inner surface 213 may be cool (relative to a condensation point of the vapor). The inner surface 213 remains cool because it is thermally coupled with heat dissipating structures 212.

As a result of the contact between portions of the vapor phase 220 coolant 216 and the inner surface 213 the heat carried by that portion of the vapor phase 220 of coolant 216 is transferred to the cover 210. Removal of the heat from that portion of the vapor phase 220 of coolant 216 causes it to condense, resulting in that portion of coolant 216 returning to the liquid phase 218. The newly condensed and cooled liquid phase 220 coolant 216, which is depicted as stylized droplets in FIGS. 8-10, may then return by gravity to the pool 217 of coolant 216 in the liquid phase, thus allowing the phase-change cycle to continue. Meanwhile, the heat transferred from coolant 216 to cover 210 may transfer by conduction to the heat dissipating structures 212 and from there the heat may be dissipated to an exterior environment. This keeps the cover 210 cool enough to allow the continued condensation of more portions of the vapor phase 220 as they come into contact with the cover 210. Thus, system board 222, and more particularly the electronic components 226 coupled thereto, may be continually cooled via the repeated phase-change of the coolant 216 and the dissipation of heat by the heat dissipating structures.

It is to be understood that both the general description and the detailed description provide example implementations that are explanatory in nature and are intended to provide an understanding of the present disclosure without limiting the scope of the present disclosure. Other examples in accordance with the present disclosure will be apparent to those skilled in the art based on consideration of the disclosure herein. For example, various mechanical, compositional, structural, electronic, and operational changes may be made to the disclosed examples without departing from the scope of this disclosure, including for example the addition, removal, alteration, substitution, or rearrangement of elements of the disclosed examples, as would be apparent to one skilled in the art in consideration of the present disclosure. Moreover, it will be apparent to those skilled in the art that certain features or aspects of the present teachings may be utilized independently (even if they are disclosed together in some examples) or may be utilized together (even if disclosed in separate examples), whenever practical. In some instances, well-known circuits, structures, and techniques have not been shown or described in detail in order not to obscure the examples. Thus, the following claims are intended to be given their fullest breadth, including equivalents, under the applicable law, without being limited to the examples disclosed herein.

References herein to examples, implementations, or other similar references should be understood as referring to prophetic or hypothetical examples, rather than to devices/systems that have been actually produced, unless explicitly indicated otherwise. Similarly, references to qualities or characteristics of examples should be understood as representing the educated estimates or expectations of the inventors based on their understanding of the relevant principles involved, application of theory and/or modeling, and/or past experiences, rather than as being representations of the actual qualities or characteristics of an actually produced device/system or the empirical results of tests actually carried out, unless explicitly indicated otherwise.

Further, spatial, positional, and relational terminology used herein is chosen to aid the reader in understanding examples of the invention but is not intended to limit the invention to a particular reference frame, orientation, or positional relationship. For example, spatial, positional, and relational terms such as “up”, “down”, “lateral”, “beneath”, “below”, “lower”, “above”, “upper”, “proximal”, “distal”, and the like may be used herein to describe directions or to describe one element's or feature's spatial relationship to another element or feature as illustrated in the figures. These spatial terms are used relative to reference frames in the figures and are not limited to a particular reference frame in the real world. Furthermore, if a different reference frame is considered than the one illustrated in the figures, then the spatial terms used herein may need to be interpreted differently in that different reference frame. Moreover, the poses of items illustrated in the figure are chosen for convenience of illustration and description, but in an implementation in practice the items may be posed differently.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition. Moreover, unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

What is claimed is:

1. An outdoor information processing device, comprising:
a housing comprising:
a hollow interior volume sealed air-tight from an exterior environment; and
heat dissipation structures on an exterior of the housing;
a coolant disposed in the hollow interior volume of the housing, a portion of the coolant being in a liquid phase collected in a pool in the housing and a portion of the coolant being in a vapor phase above the pool; and
an information processing system board comprising electronic components disposed in the hollow interior volume and immersed in the pool of the liquid phase of the coolant,
wherein the coolant is configured to transfer heat from the electronic components into the housing via the coolant going through a repeated phase-change cycle.

2. The outdoor information processing device of claim 1, wherein the repeated phase-change cycle comprises boiling from the liquid phase into the vapor phase, convection, condensation from the vapor phase onto the housing into the liquid phase, and return to the pool.

3. The outdoor information processing device of claim 1, wherein:
the housing comprises:
a housing body defining the hollow interior volume;
a cover to selectively engage with the housing body, wherein in an engaged state of the cover with the housing body, the hollow interior volume is sealed against an external environment; and
the heat dissipation structures are disposed on the cover of the housing.

4. The outdoor information processing device of claim 1, wherein the heat dissipation structures comprise a heat sink.

5. The outdoor information processing device of claim 1, wherein the heat dissipation structures further comprise a plurality of heat dissipating fins on an external surface of the housing.

6. The outdoor information processing device of claim 1, wherein:
the housing has a diameter of between 200 millimeters and 300 millimeters; and
the housing has a weight of between 2 kilograms and 5 kilograms.

7. The outdoor information processing device of claim 1, wherein the coolant is a dielectric fluid.

8. The outdoor information processing device of claim 1, wherein the coolant has a boiling point that is lower than or equal to a lowest maximum operating temperature of the electronic components of the system board.

9. The outdoor information processing device of claim 1, wherein the coolant has a boiling point of between 97 and 99 degrees Celsius.

10. The outdoor information processing device of claim 1, wherein the outdoor information processing device is an outdoor wireless access point.

11. The outdoor information processing device of claim 1, further comprising an electrical interface coupled to an exterior of the housing, electrically connected to the system board through the housing, and configured to supply electrical power to and exchange electrical communications with the system board.

12. The outdoor information processing device of claim 11, wherein the electrical interface comprises one or more ethernet connectors.

13. The outdoor information processing device of claim 11, wherein the electrical interface comprises one or more antennae.

14. The outdoor information processing device of claim 11, wherein the electrical interface comprises a power input port.

15. The outdoor information processing device of claim 1, further comprising a mounting feature on the housing, the mounting feature configured to mount the outdoor information processing device to a bracket, wherein the bracket is one of a wall bracket and a ceiling bracket.

16. A system, comprising:
an outdoor information processing device, the outdoor information processing device comprising:
a housing, the housing comprising:
a housing body defining a hollow interior volume;
a cover to engage with the housing body to seal the hollow interior volume air-tight from an exterior environment; and
heat dissipation structures on an exterior of the housing;
a coolant disposed in the hollow interior volume of the housing, a portion of the coolant being in a liquid phase collected in a pool in the housing and a portion of the coolant being in a vapor phase above the pool;
a system board comprising electronic components disposed in the hollow interior volume of the housing body, wherein the system board is immersed in the pool of the liquid phase of the coolant; and
a power source, external to the housing, electrically connected to the system board via an electrical interface coupled to an exterior of the housing.

17. The system of claim 16, further comprising a data communication device external to the housing and electrically connected to the system board via the electrical interface.

18. The system of claim 16, wherein the coolant is configured to transfer heat from the electronic components into the housing via the coolant going through a repeated phase-change cycle, the repeated phase-change cycle comprising boiling from the liquid phase into the vapor phase, convection, condensation from the vapor phase onto the housing into the liquid phase, and return to the pool.

19. The system of claim 16, wherein the coolant is a dielectric fluid having a boiling point that is less than or equal to a lowest specified maximum operating temperature of the electronic components of the system board.

20. A system, comprising:
an outdoor information processing device, the outdoor information processing device comprising:
a housing, the housing comprising:
a housing body defining a hollow interior volume;
a cover to engage with the housing body to seal the hollow interior volume air-tight from an exterior environment; and
heat dissipation structures on an exterior of the housing;
a coolant disposed in the hollow interior volume of the housing, a portion of the coolant being in a liquid phase collected in a pool in the housing and a portion of the coolant being in a vapor phase above the pool, wherein the coolant further comprises a dielectric fluid;
a system board comprising electronic components disposed in the hollow interior volume of the housing body, wherein the system board is immersed in the pool of the liquid phase of the coolant;
a power source, external to the housing, electrically connected to the system board via an electrical interface coupled to an exterior of the housing;
a data communication device external to the housing and electrically connected to the system board via the electrical interface; and
a mounting feature coupled to the housing body and configured to engage with a corresponding mounting bracket on an external surface.
